(19) United States
(12) Patent Application Publication
(10) Pub. No.: US 2009/0065807 A1
(43) Pub. Date: Mar. 12, 2009

(54) SEMICONDUCTOR DEVICE AND FABRICATION METHOD FOR THE SAME

(76) Inventor: Hiromasa FUJIMOTO, Osaka (JP)

Correspondence Address: MCDERMOTT WILL & EMERY LLP, 600 13TH STREET, NW, WASHINGTON, DC, 20005-3096, US

(21) Appl. No.: 12/201,407

(22) Filed: Aug. 29, 2008

(30) Foreign Application Priority Data
Sep. 7, 2007 (JP) 2007-232556

(51) Int. Cl. H01L 27/092; H01L 21/8238

(52) U.S. Cl. 257/190; 438/231; 257/E27.062; 257/E21.632

(57) ABSTRACT

The semiconductor device includes: a first MIS transistor formed on a first region of a first conductivity type in a semiconductor substrate; and a second MIS transistor formed on a second region of a second conductivity type in the semiconductor substrate. The first MIS transistor has a first gate insulating film and a first gate electrode formed on the first region, first sidewalls formed on the side faces of the first gate electrode, and first source/drain regions made of silicon formed in portions of the first region. The second MIS transistor has a second gate insulating film and a second gate electrode formed on the second region, second sidewalls formed on the side faces of the second gate electrode, and second source/drain regions including silicon germanium formed in portions of the second region. The second sidewalls are smaller in height than the first sidewalls.

### CROSS-REFERENCE TO RELATED APPLICATIONS

This application claims priority under 35 U.S.C. §119 on Patent Application No. 2007-232556 filed in Japan on Sep. 7, 2007, the entire contents of which are hereby incorporated by reference.

### BACKGROUND OF THE INVENTION

The present invention relates to a semiconductor device and a fabrication method for the same, and more particularly to a semiconductor device in which stress strain is imparted to the channel region of a metal-insulator semiconductor (MIS) transistor and a fabrication method for such a semiconductor device.

In recent years, along with implementation of semiconductor integrated circuit devices with higher integration, higher performance and higher speed, there has been proposed a technology of improving the carrier mobility by imparting stress strain to the semiconductor substrate. For example, the mobility of electrons improves by imparting tensile stress strain to an n-type MIS transistor formed on the principal surface of a silicon substrate that has (100) plane as its principal surface, and this increases the transistor driving force.

The direction of optimum stress strain is however different between an n-type MIS transistor (hereinafter, referred to as an n-type transistor) and a p-type MIS transistor (hereinafter, referred to as a p-type transistor). To cope with this problem, proposed is a technology of producing stress strain suitable for each of the n-type transistor and the p-type transistor.

Hereinafter, a fabrication method for a semiconductor device in which stress strain is produced for an n-type transistor and a p-type transistor separately will be described with reference to FIGS. 8A to 8D, 9A to 9D and 10A to 10D (see “International Electron Devices Meeting (IEDM) 2005 technical digest”, pp. 61-64, for example).

First, as shown in FIG. 8A, the principal surface of a semiconductor substrate 101 made of silicon is partitioned into an n-type transistor region A and a p-type transistor region B with an isolation region 102. A p-type well 103 is then formed in the n-type transistor region A of the semiconductor substrate 101, and an n-type well 104 is formed in the p-type transistor region B thereof. Thereafter, an n-type gate electrode 106 and a p-type gate electrode 107 both made of polysilicon are formed, by patterning with a hard mask 108, on the n-type transistor region A and the p-type transistor region B, respectively, with respective gate insulating films 105 interposed therebetween. Sidewall films 109 are then formed on the side faces of the gate electrodes 106 and 107. Using the sidewall films 109, the hard mask 108 and the n-type gate electrode 106 as a mask, n-type extension regions 110 are formed in the n-type transistor region A. Likewise, using the sidewall films 109, the hard mask 108 and the p-type gate electrode 107 as a mask, p-type extension regions 111 are formed in the p-type transistor region B.

As shown in FIG. 8B, a two-layer insulating film is deposited over the entire surface of the semiconductor substrate 101, and the deposited insulating film is etched back, to form sidewalls 112 on the side faces of the n-type gate electrode 106 and the p-type gate electrode 107 with the sidewall films 109 interposed therebetween.

As shown in FIG. 8C, a first resist pattern 201 having an opening corresponding to the n-type transistor region A is formed on the semiconductor substrate 101. The hard mask 108 on the n-type gate electrode 106 exposed in the opening is then removed, and thereafter, arsenic (As) is implanted in the semiconductor substrate 101 using the first resist pattern 201, the n-type gate electrode 106, the sidewall films 109 and the sidewalls 112 as a mask, to form n-type source/drain regions 113 in portions of the upper part of the p-type well 103 located outside of the sidewalls 112.

As shown in FIG. 8D, after removal of the first resist pattern 201, a silicon oxide film 114 and then a silicon nitride film 115 are deposited on the entire surface of the semiconductor substrate 101. Note that the silicon nitride film 115 is formed under conditions in which tensile stress strain in the gate length direction will be produced in the channel region under the n-type gate electrode 106.

As shown in FIG. 9A, a second resist pattern 202 having an opening corresponding to the p-type transistor region B is formed on the semiconductor substrate 101. Using the second resist pattern 202 as a mask, the portion of the silicon nitride film 115 formed on the p-type transistor region B is removed. The second resist pattern 202 is then removed, and annealing is made for the resultant semiconductor substrate 101, to produce tensile stress strain in the gate length direction in the channel region under the n-type gate electrode 106.

As shown in FIG. 9B, the silicon nitride film 115 and the silicon oxide film 114 are sequentially removed.

As shown in FIG. 9C, a protection film 116 made of silicon oxide is formed over the entire surface of the semiconductor substrate 101.

As shown in FIG. 9D, a third resist pattern 203 having an opening corresponding to the p-type transistor region B is formed on the semiconductor substrate 101. Using the third resist pattern 203 as a mask, the portion of the protection film 116 formed on the p-type transistor region B is removed. Also, the semiconductor substrate 101 is etched using the third resist pattern 203, the hard mask 108, the sidewall films 109 and the sidewalls 112 as a mask, to form recesses 104a in portions of the upper part of the n-type well 104 located outside of the sidewalls 112.

As shown in FIG. 10A, after removal of the third resist pattern 203, while the n-type transistor region A being covered with the protection film 116, semiconductor layers 117A made of silicon germanium (SiGe) are grown in the recesses 104a formed in the p-type transistor region B by selective epitaxy. Having such semiconductor layers 117A made of mixed crystal including Ge larger in lattice constant than Si, compressive stress strain occurs in the gate length direction in the channel region under the p-type gate electrode 107.

As shown in FIG. 10B, the protection film 116 covering the n-type transistor region A is removed.

As shown in FIG. 10C, a fourth resist pattern 204 having an opening corresponding to the p-type transistor region B is formed on the semiconductor substrate 101. Using the fourth resist pattern 204 as a mask, the hard mask 108 on the p-type gate electrode 107 is removed. Subsequently, boron (B) is implanted in the semiconductor substrate 101 using the fourth resist pattern 204, the p-type gate electrode 107, the sidewall films 109 and the sidewalls 112 as a mask, to form p-type source/drain regions 117 in the semiconductor layer 117A made of SiGe.

As shown in FIG. 10D, after removal of the fourth resist pattern 204, a metal layer is deposited on the resultant semiconductor substrate 101. The deposited metal layer is then annealed, to form metal silicide layers 118 in the upper portions of the n-type source/drain regions 113, the n-type gate electrode 106, the p-type source/drain regions 117 and the p-type gate electrode 107.

In the manner described above, it is possible to produce tensile stress strain in the n-type transistor region A while producing compressive stress strain in the p-type transistor region B.

However, in the conventional fabrication method for a semiconductor device described above, in which different types of stress must be produced in the channel regions of the n-type transistor region A and the p-type transistor region B, the fabrication process is disadvantageously complicated.

### SUMMARY OF THE INVENTION

An object of the present invention is providing a simpler method for fabricating a semiconductor device in which different types of stress are produced for MIS transistors different in conductivity type.

To attain the above object, according to the present invention, an insulating film provided for producing tensile stress strain in the channel region of a first transistor is used as a mask for selective formation of silicon germanium layers in the source/drain formation regions of a second transistor.

Specifically, the semiconductor device of the present invention includes: a first MIS transistor formed on a first region of a first conductivity type in a semiconductor substrate; and a second MIS transistor formed on a second region of a second conductivity type in the semiconductor substrate, wherein the first MIS transistor has a first gate insulating film and a first gate electrode formed on the first region, first sidewalls formed on side faces of the first gate electrode, and first source/drain regions of the second conductivity type made of silicon formed in portions of the first region located outside of the first sidewalls, the second MIS transistor has a second gate insulating film and a second gate electrode formed on the second region, second sidewalls formed on side faces of the second gate electrode, and second source/drain regions of the first conductivity type including silicon germanium formed in portions of the second region located outside of the second sidewalls, and the second sidewalls are smaller in height than the first sidewalls.

According to the semiconductor device of the present invention, the first gate electrode and the first sidewalls are covered with an insulating film for producing stress strain during fabrication according to the fabrication method of the present invention. In contrast, the second gate electrode and the second sidewalls are not covered with such an insulating film for producing stress strain, and thus the second sidewalls become smaller in at least height than the first sidewalls by being subjected to various types of etching and the like during fabrication.

In the semiconductor device of the invention, the second sidewalls are preferably smaller in width than the first sidewalls.

Preferably, the semiconductor device of the invention further includes: recesses formed in portions of the second region located outside of the second sidewalls; and semiconductor regions made of silicon germanium formed in the recesses in contact with the semiconductor substrate, wherein the second source/drain regions are formed in the semiconductor regions.

In the above case, the proportion of germanium in the semiconductor regions is preferably not less than 15% and not more than 30%.

In the above case, also, the top surfaces of the semiconductor regions may protrude upward from the surface of a portion of the second region located under the second gate electrode.

In the semiconductor device of the invention, preferably, tensile stress strain occurs in the gate length direction in a channel region of the first region located under the first gate electrode, and compressive stress strain occurs in the gate length direction in a channel region of the second region located under the second gate electrode.

In the semiconductor device of the invention, preferably, the main component of the first gate electrode and the second gate electrode is silicon, and the grain size of silicon crystal in the first gate electrode is greater than the grain size of silicon crystal in the second gate electrode.

Having such a greater grain size of silicon crystal, tensile stress strain in the gate length direction can further be produced in the channel region of the first region located under the first gate electrode.

Preferably, the semiconductor device of the invention further includes: a first insulating film formed on the first region to cover the first sidewalls and the first gate electrode and also to produce tensile stress strain in the gate length direction; and a second insulating film formed on the second region to cover the second sidewalls and the second gate electrode and also to produce compressive stress strain in the gate length direction In the semiconductor device of the invention, metal silicide layers are preferably formed in upper portions of the first source/drain regions, the first gate electrode, the second source/drain regions and the second gate electrode.

The fabrication method for a semiconductor device of the present invention includes the steps of: (a) forming a first gate insulating film and a first gate electrode, in this order, on a first region of a first conductivity type in a semiconductor substrate, and forming a second gate insulating film and a second gate electrode, in this order, on a second region of a second conductivity type in the semiconductor substrate; (b) forming first sidewalls and second sidewalls, both being insulative, on both side faces of the first gate electrode and the second gate electrode, respectively; (c) forming a first insulating film on the first region to cover the first sidewalls and the first gate electrode and to impart stress strain to the first region; (d) imparting stress strain to the first region by means of the first insulating film by heating the semiconductor substrate; (e) after the step (d), forming recesses in the second region to be located outside of the second sidewalls by etching upper portions of the second region using the first insulating film on the first region and the second sidewalls on the second region as a mask; and (f) forming semiconductor regions made of silicon germanium in the recesses in the second region.

According to the fabrication method for a semiconductor device of the present invention, the first insulating film for producing stress strain in the first region is used as it is as a mask film for formation of recesses in the second region. This eliminates the necessity of a new mask film such as a resist pattern. Hence, a semiconductor device in which different types of stress are produced in the first and second regions different in conductivity type can be fabricated more simply.

In the fabrication method of the invention, preferably, the step (a) includes the step of forming a first hard mask on the first gate electrode and forming a second hard mask on lo the second gate electrode, and in the step (e), recesses are formed by etching upper portions of the second region using the second hard mask and the second sidewalls as a mask.

Preferably, the fabrication method of the invention further includes, between the step (b) and the step (c), the step of: (g) forming first source/drain regions of the second conductivity type by implanting an impurity of the second conductivity type in the first region selectively using the first gate electrode and the first sidewalls as a mask.

In the above case, preferably, the main component of the first gate electrode is silicon, and in the step (g), the impurity of the second conductivity type is implanted after removal of the first hard mask, to allow the impurity of the second conductivity type to be implanted also in the first gate electrode.

Preferably, the fabrication method of the invention further includes, after the step (f), the step of: (h) forming second source/drain regions of the first conductivity type in the semiconductor regions by implanting an impurity of the first conductivity type in the semiconductor regions in the second region selectively using the second gate electrode and the second sidewalls as a mask.

In the above case, in the step (h), the first region is preferably covered with the first insulating film.

By adopting the above way, it is possible to omit the step of newly forming a mask pattern with a resist and the like.

Alternatively, in the above case, in the step (h), the first region is preferably covered with a mask pattern covering the first insulating film.

By adopting the above way, the first insulating film can be thinned, and thus further scaling-down can be implemented.

Preferably, the fabrication method of the invention further includes, after the step (f), the step of (i) removing the first insulating film on the first region, wherein in the step (i), the second sidewalls become smaller in height than the first sidewalls.

Preferably, the fabrication method of the invention further includes, after the step (i), the step of: (j) removing the first sidewalls and the second sidewalls.

In the above case, preferably, in the step (b), each of the first sidewalls and the second sidewalls is formed of a plurality of insulating films different in composition, and in the step (j), only the outer one of the plurality of insulating films constituting each of the first sidewalls and the second sidewalls is selectively removed.

In the fabrication method of the invention, the step (c) preferably includes the step of forming a second insulating film different in composition from the first insulating film before the formation of the first insulating film.

### BRIEF DESCRIPTION OF THE DRAWINGS

FIGS. 1A to 1D are cross-sectional views sequentially illustrating process steps of a fabrication method for a semiconductor device of Embodiment 1 of the present invention.

FIGS. 2A to 2D are cross-sectional views sequentially illustrating process steps of the fabrication method of Embodiment 1 of the present invention.

FIGS. 3A to 3C are cross-sectional views sequentially illustrating process steps of the fabrication method of Embodiment 1 of the present invention.

FIGS. 4A to 4C are cross-sectional views sequentially illustrating process steps (main steps) of a fabrication method for a semiconductor device as an alteration to Embodiment 1 of the present invention.

FIGS. 5A to 5D are cross-sectional views sequentially illustrating process steps of a fabrication method for a semiconductor device of Embodiment 2 of the present invention.

FIGS. 6A to 6D are cross-sectional views sequentially illustrating process steps of the fabrication method of Embodiment 2 of the present invention.

FIGS. 7A to 7C are cross-sectional views sequentially illustrating process steps of the fabrication method of Embodiment 2 of the present invention.

FIGS. 8A to 8D are cross-sectional views sequentially illustrating process steps of a conventional fabrication method for a semiconductor device.

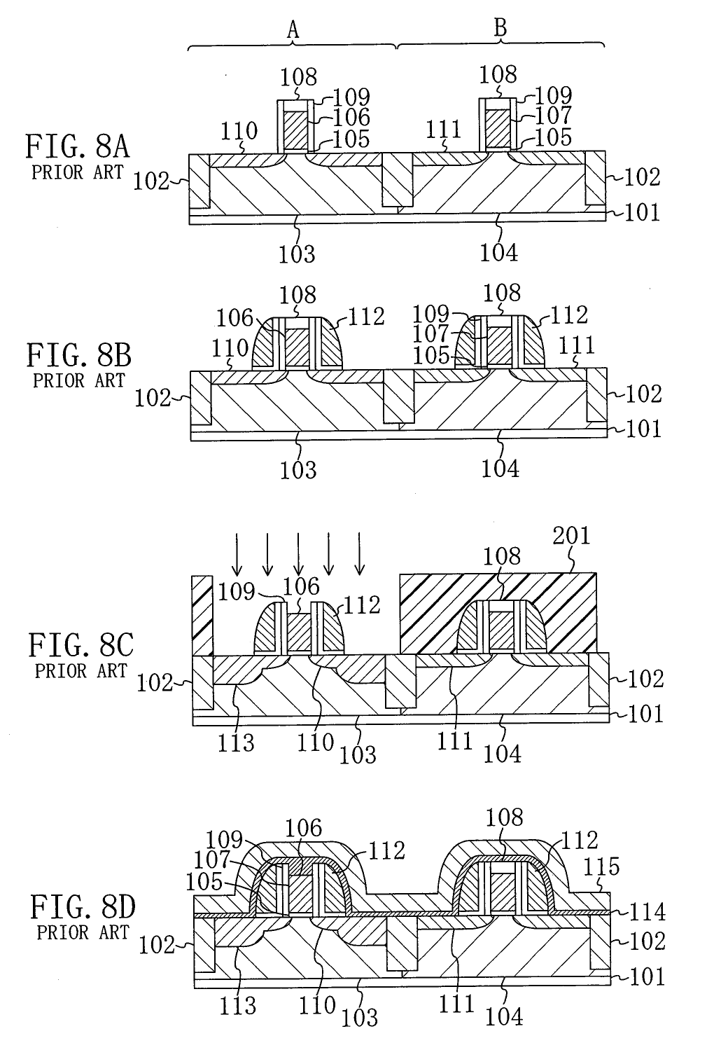

FIGS. 9A to 9D are cross-sectional views sequentially illustrating process steps of the conventional fabrication method.

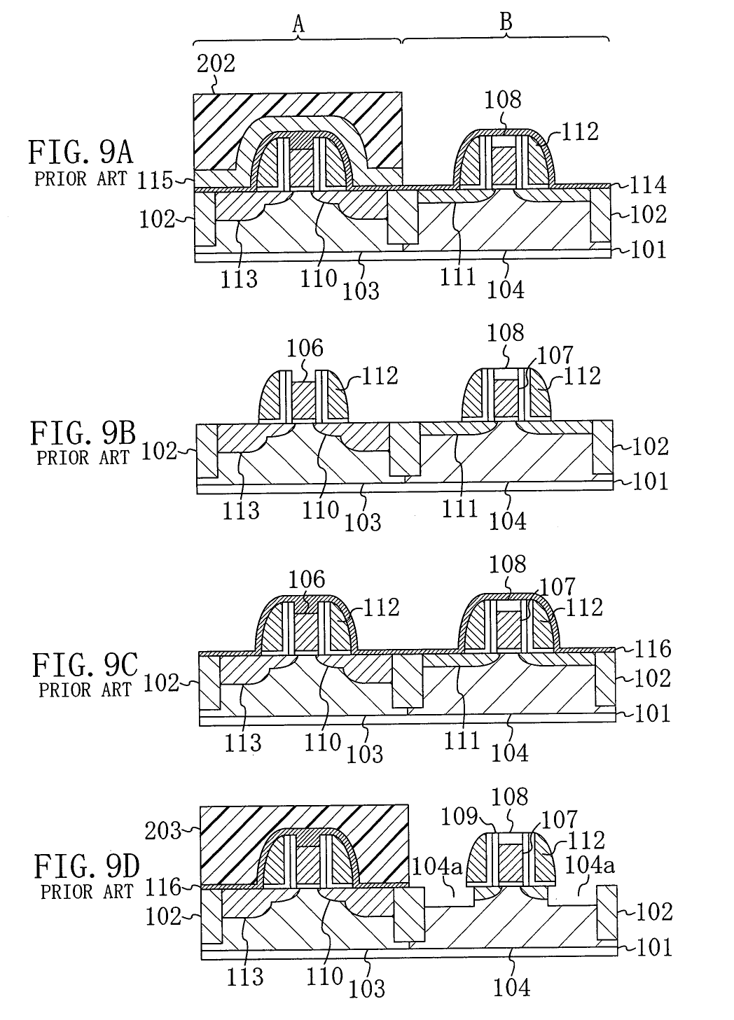

FIGS. 10A to 10D are cross-sectional views sequentially illustrating process steps of the conventional fabrication method.

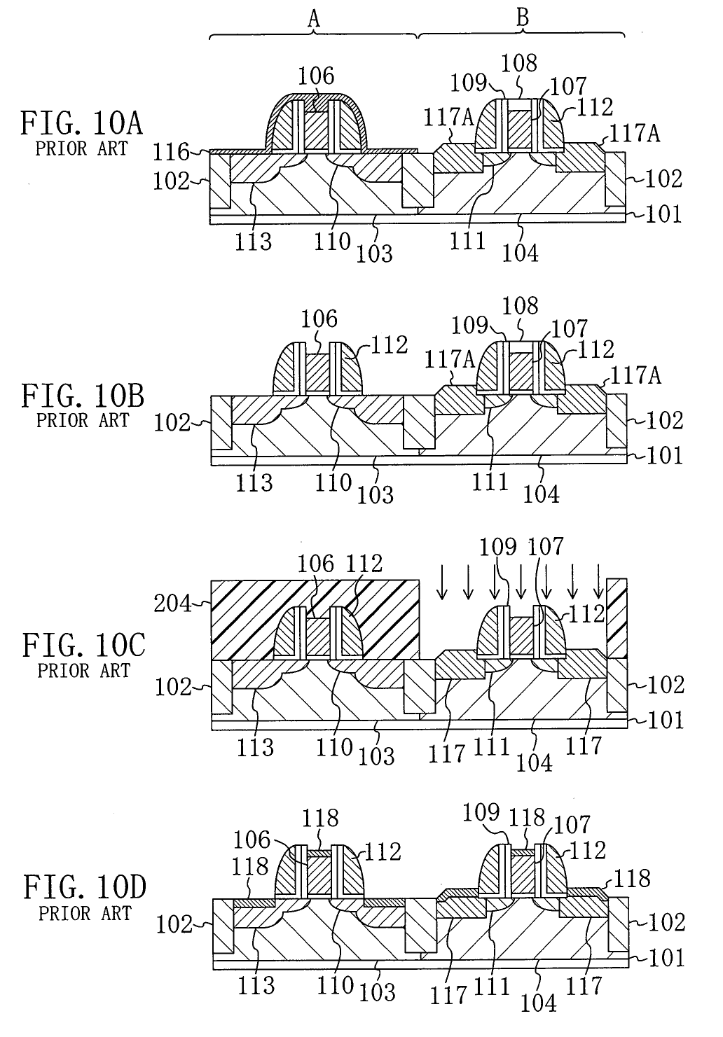

### DESCRIPTION OF THE PREFERRED EMBODIMENTS

### Embodiment 1

A fabrication method for a semiconductor device of Embodiment 1 of the present invention will be described with reference to the relevant drawings.

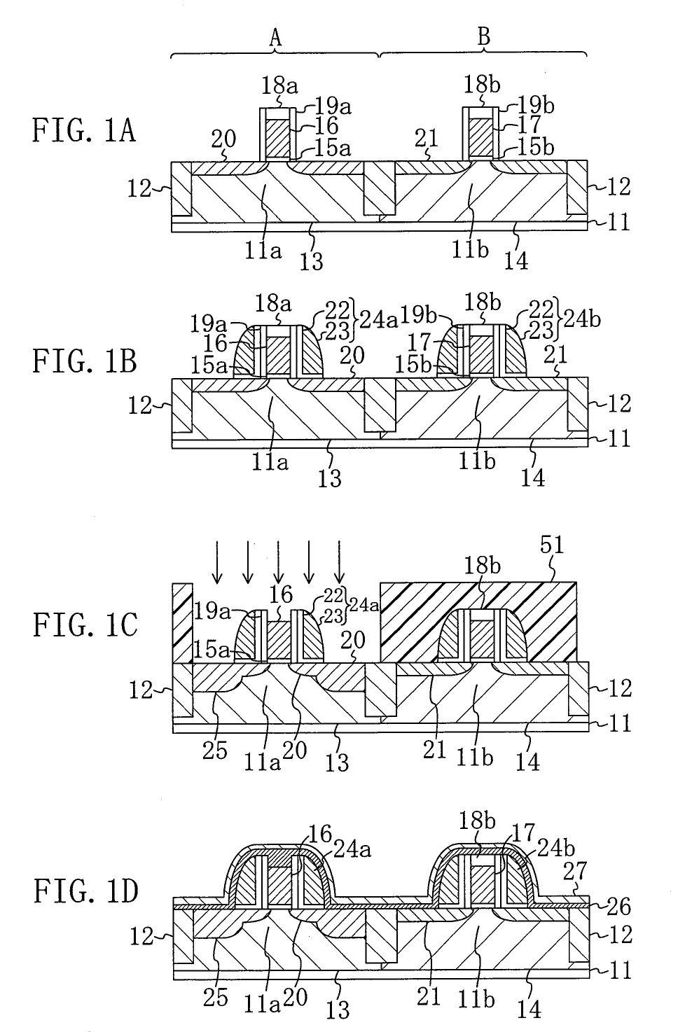

FIGS. 1A to 1D, 2A to 2D and 3A to 3C are cross-sectional views sequentially illustrating process steps of a fabrication method for a semiconductor device of Embodiment 1 of the present invention.

First, as shown in FIG. 1A, the principal surface of a semiconductor substrate 11 made of silicon (Si), which has (100) plane as its principal surface, is partitioned into an n-type transistor region A and a p-type transistor region B with an isolation region 12. An active region 11a is therefore formed as a portion of the semiconductor substrate 11 surrounded with the isolation region 12 in the n-type transistor region A, and an active region 11b is formed as a portion of the semiconductor substrate 11 surrounded with the isolation region 12 in the p-type transistor region B. A p-type well 13 is then formed in the n-type transistor region A of the semiconductor substrate 11, and an n-type well 14 is formed in the p-type transistor region A thereof. Thereafter, an n-type gate electrode 16 made of polysilicon is formed, by patterning with a hard mask 18a, on the active region 11a in the n-type transistor region A with a gate insulating film 15a interposed therebetween. Likewise, a p-type gate electrode 17 made of polysilicon is formed, by patterning with a hard mask 18b, on the active region 11b in the p-type transistor region B with a gate insulating film 15b interposed therebetween. As the hard masks 18a and 18b, a silicon oxide (SiO₂) film having a thickness of about 60 nm to 80 nm may be used. Sidewall films (sidewall spacers) 19a and 19b made of silicon oxide (SiO₂) are then formed on the side faces of the gate electrodes 16 and 17, respectively. Using the sidewall films 19a, the hard mask 18a and the n-type gate electrode 16 as a mask, an n-type impurity is implanted to form n-type extension regions 20 in the active region 11a in the n-type transistor region A. Likewise, using the sidewall films 19b, the hard mask 18b and the p-type gate electrode 17 as a mask, a p-type impurity is implanted to form p-type extension regions 21 in the active region 11b in the p-type transistor region B.

As shown in FIG. 1B, a multilayer film made of a silicon oxide film 22 and a silicon nitride film 23, for example, is deposited over the entire surface of the semiconductor substrate 11, and the deposited multilayer film is etched back, to form sidewalls 24a and 24b on the side faces of the n-type gate electrode 16 and the p-type gate electrode 17, respectively, with the sidewall films 19a and 19b interposed therebetween. Each of the sidewalls 24a and 24b is composed of an inner sidewall of the silicon oxide film 22 having an L-shaped cross section and an outer sidewall of the silicon nitride film 23 formed on the inner sidewall. The sidewalls 24a and 24b are not necessarily made of a multilayer film.

As shown in FIG. 1C, a first resist pattern 51 having an opening corresponding to the n-type transistor region A is formed on the semiconductor substrate 11. The hard mask 18a on the n-type gate electrode 16 exposed in the opening of the first resist pattern 51 is then removed by wet etching with buffered hydrogen fluoride (BHF) and the like, and thereafter, arsenic (As) is implanted in the active region 11a using the first resist pattern 51, the n-type gate electrode 16, the sidewall films 19a and the sidewalls 24a as a mask, to form n-type source/drain regions 25 in portions of the upper part of the p-type well 13 located outside of the sidewalls 24a. During this implantation, arsenic is also implanted in the n-type gate electrode 16, and this makes the grain size of the polysilicon constituting the n-type gate electrode 16 larger than the grain size of the polysilicon constituting the p-type gate electrode 17. With this enlarging of polysilicon, tensile stress strain in the gate length direction occurs in the channel region of the active region 11a located under the n-type gate electrode 16.

As shown in FIG. 1D, the first resist pattern 51 is removed, and thereafter, an underlying film 26 made of silicon oxide and a stress strain producing film 27 made of silicon nitride are sequentially deposited on the entire surface of the semiconductor substrate 11 by chemical vapor deposition (CVD) so as to cover the n-type gate electrode 16 together with the sidewall films 19a and the sidewalls 24a and also the hard mask 18b on the p-type gate electrode 17 together with the sidewall films 19b and the sidewalls 24b. In the illustrated example, the thickness of the underlying film 26 is about 5 nm to 15 nm, and the thickness of the stress strain producing film 27 is about 15 nm to 20 nm, specifically about 20 nm. The stress strain producing film 27 is formed under conditions with which tensile stress strain in the gate length direction will be produced in the channel region of the active region 11a under the n-type gate electrode 16. The underlying film 26 is not necessarily provided.

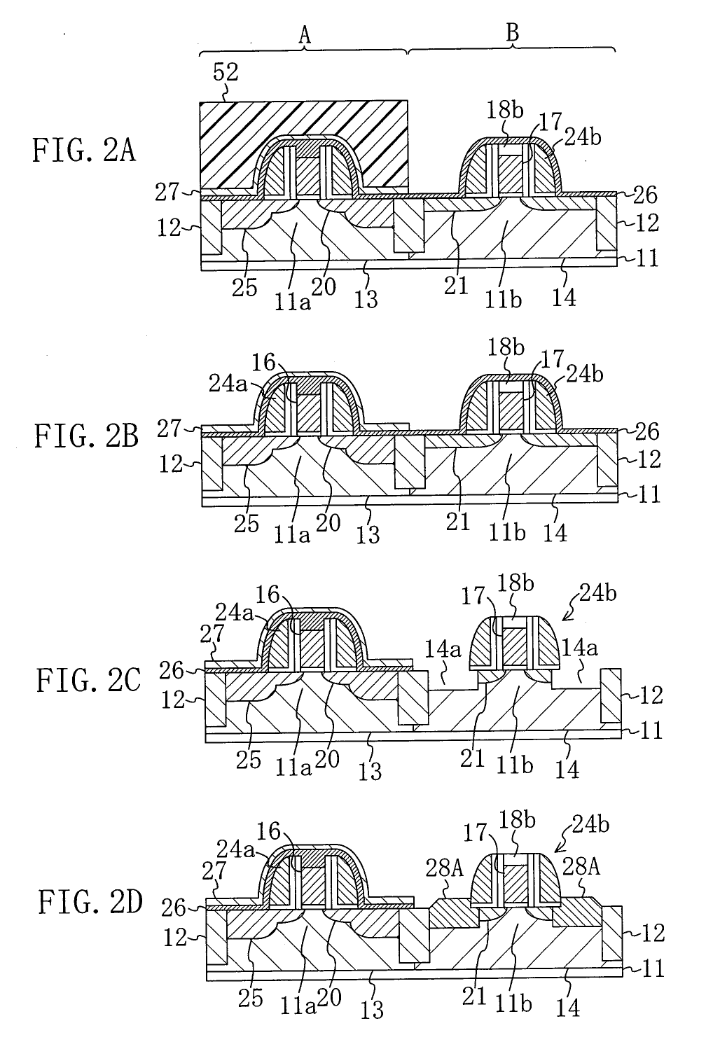

As shown in FIG. 2A, a second resist pattern 52 having an opening corresponding to the p-type transistor region B is formed on the semiconductor substrate 11. Using the second resist pattern 52 as a mask, the portion of the stress strain producing film 27 formed on the p-type transistor region B is removed with hot phosphoric acid and the like.

As shown in FIG. 2B, the second resist pattern 52 is removed, and thereafter, annealing is made for the resultant semiconductor substrate 11 at about 1050° C. for about 0 to 10 seconds, to produce tensile stress strain in the gate length direction in the channel region of the active region 11a under the n-type gate electrode 16.

As shown in FIG. 2C, the underlying film 26 formed on the p-type transistor region B is removed with buffered hydrogen fluoride (BHF) and the like using the stress strain producing film 27 on the n-type transistor region A as a mask. Subsequently, the portions of the active region 11b (semiconductor substrate 11) exposed in the p-type transistor region B are etched using the stress strain producing film 27 on the n-type transistor region A and the hard mask 18b, the sidewall films 19b and the sidewalls 24b on the p-type transistor region B as a mask. With this etching, recesses 14a are formed in portions of the upper part of the n-type well 14 in the active region 11b located outside of the sidewalls 24b. The depth of the recesses 14a is desirably about 40 nm to 60 nm when the height of the p-type gate electrode 17 is 100 nm.

As shown in FIG. 2D, while the active region 11a in the n-type transistor region A is kept covered with the stress strain producing film 27 and the underlying film 26, semiconductor layers 28A made of silicon germanium (SiGe) are epitaxially grown in the recesses 14a formed in the active region 11b selectively by metal-organic chemical vapor deposition (MOCVD), for example. Having such semiconductor layers 28A made of mixed crystal including Ge larger in lattice constant than Si, compressive stress strain in the gate length direction occurs in the channel region of the active region 11b under the p-type gate electrode 17. The proportion of Ge in SiGe is desirably about 15% to 30%. The protrusion of the semiconductor layers 28A from the principal surface of the semiconductor substrate 11 is desirably about 20% to 30% of the height of the p-type gate electrode 17.

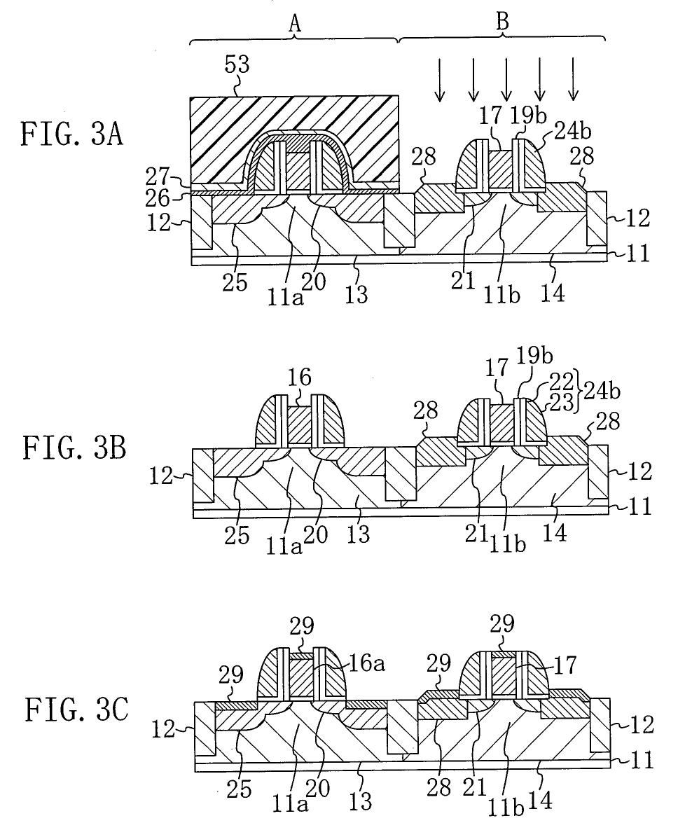

As shown in FIG. 3A, a third resist pattern 53 having an opening corresponding to the p-type transistor region B is formed on the semiconductor substrate 11. Using the third resist pattern 53 as a mask, the hard mask 18b on the p-type gate electrode 17 is removed. Subsequently, boron (B) is implanted in the active region 11b using the third resist pattern 53, the p-type gate electrode 17, the sidewall films 19b and the sidewalls 24b as a mask, to form p-type source/drain regions 28 in the active region 11b including the semiconductor layers 28A made of SiGe.

As shown in FIG. 3B, the third resist pattern 53 is removed, and thereafter, the stress strain producing film 27 and the underlying film 26 covering the n-type transistor region A on the semiconductor substrate 11 are removed by anisotropy etching such as dry etching with sulfur hexafluoride (SF₆) as a main ingredient. With this dry etching for removing the stress strain producing film 27 and the underlying film 26, the sidewalls 24b each made of the silicon oxide film 22 and the silicon nitride film 23 and the sidewall films 19b made of silicon oxide formed on the side faces of the p-type gate electrode 17 are thinned. Therefore, the height and width of the sidewalls 24b become smaller than the height and width of the sidewalls 24a formed on the side faces of the n-type gate electrode 16.

As shown in FIG. 3C, a metal layer made of nickel (Ni), cobalt (Co), platinum (Pt) or the like is deposited on the resultant semiconductor substrate 11 by sputtering and the like, and the deposited metal layer is annealed, to form metal silicide layers 29 in the upper portions of the n-type source/drain regions 25, the n-type gate electrode 16, the p-type source/drain regions 28 (including the semiconductor layers 28A made of SiGe) and the p-type gate electrode 17.

By following the process described above, it is possible to implement a semiconductor device in which tensile stress strain in the gate length direction occurs in the channel region of the active region 11a in the n-type transistor region A while compressive stress strain in the gate length direction occurs in the channel region of the active region 11b in the p-type transistor region B.

Moreover, in Embodiment 1, as shown in FIG. 2C, the stress strain producing film 27 for producing tensile stress strain in the channel region in the n-type transistor region A is used as an etching mask for formation of the recesses 14a in the p-type transistor region B. This shortens and simplifies the semiconductor device fabrication process.

### Alteration to Embodiment 1

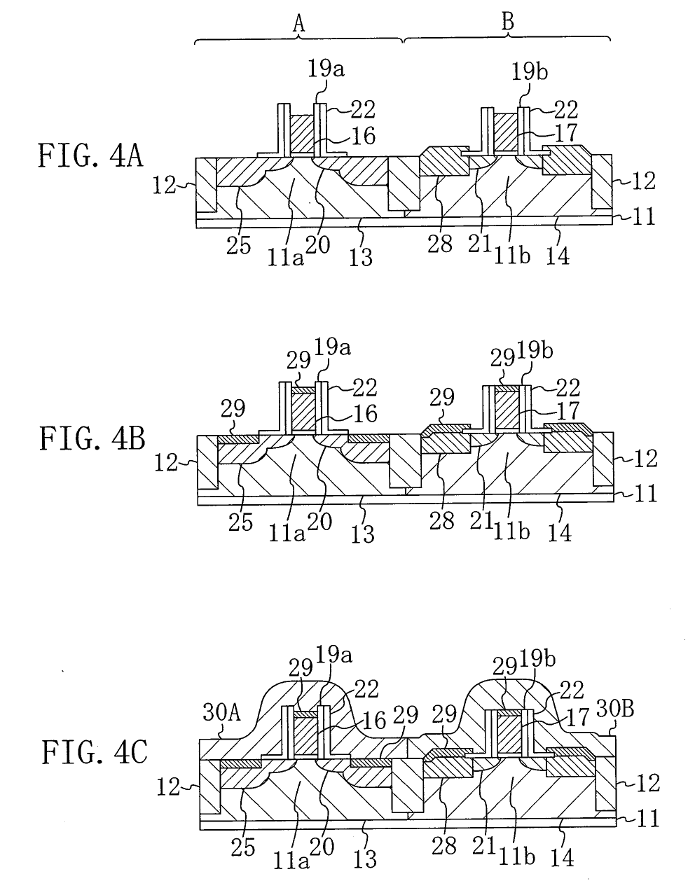

A fabrication method for a semiconductor device of an alteration to Embodiment 1 of the present invention will be described with reference to FIGS. 4A to 4C, in which the same components as those in FIGS. 3A to 3C are denoted by the same reference numerals, and description thereof is omitted here.

FIG. 4A shows a process step to be executed after the process step shown in FIG. 3B in the fabrication method for a semiconductor device of Embodiment 1, as an alternation to Embodiment 1.

Specifically, the silicon nitride film 23 located outside, among the silicon oxide film 22 and the silicon nitride film 23 constituting each of the sidewalls 24a and 24b on the n-type gate electrode 16 and the p-type gate electrode 17, is selectively removed with hot phosphoric acid, for example.

As shown in FIG. 4B, as in Embodiment 1, a metal layer made of Ni, Co or Pt, for example, is deposited on the resultant semiconductor substrate 11 by sputtering and the like, and the deposited metal layer is annealed, to form metal silicide layers 29 in the upper portions of the n-type source/drain regions 25, the n-type gate electrode 16, the p-type source/drain regions 28 (including the semiconductor layers 28A made of SiGe) and the p-type gate electrode 17.

As shown in FIG. 4C, a first stress strain producing film 30A for producing tensile stress strain in the gate length direction in the channel region under the n-type gate electrode 16 is selectively formed on the n-type transistor region A of the semiconductor substrate 11. Likewise, a second stress strain producing film 30B for producing compressive stress strain in the gate length direction in the channel region under the p-type gate electrode 17 is selectively formed on the p-type transistor region B of the semiconductor substrate 11.

As described above, the comparatively thick silicon nitride films 23 located outside, among the silicon oxide film 22 and the silicon nitride film 23 constituting each of the sidewalls 24a and 24b, is removed. In a later process step, the first and second stress strain producing films 30A and 30B respectively producing tensile stress strain and compressive stress strain are selectively formed on the semiconductor substrate 11. This permits the first and second stress strain producing films 30A and 30B to be placed closer to the respective channel regions under the n-type and p-type gate electrodes 16 and 17, and thus the strain amounts in the active regions 11a and 11b can be increased independently and more effectively.

Both the first and second stress strain producing films 30A and 30B can be formed of silicon nitride (SiN). For example, the first stress strain producing film 30A for producing tensile stress strain can be achieved by first depositing silicon nitride (SiN) by CVD at a temperature of 400° C. to 450° C., for example, and then subjecting the resultant film to ultraviolet (UV) radiation to increase the proportion of bonding between Si and H in the bonding of Si and N with hydrogen (H) contained in the silicon nitride. In reverse to the first stress strain producing film 30A, the second stress strain producing film 30B for producing compressive stress strain can be achieved by decreasing the proportion of bonding between Si and H.

In this alteration, the film thickness of the first and second stress strain producing films 30A and 30B is about 20 nm to 50 nm.

### Embodiment 2

A fabrication method for a semiconductor device of Embodiment 2 of the present invention will be described with reference to the relevant drawings.

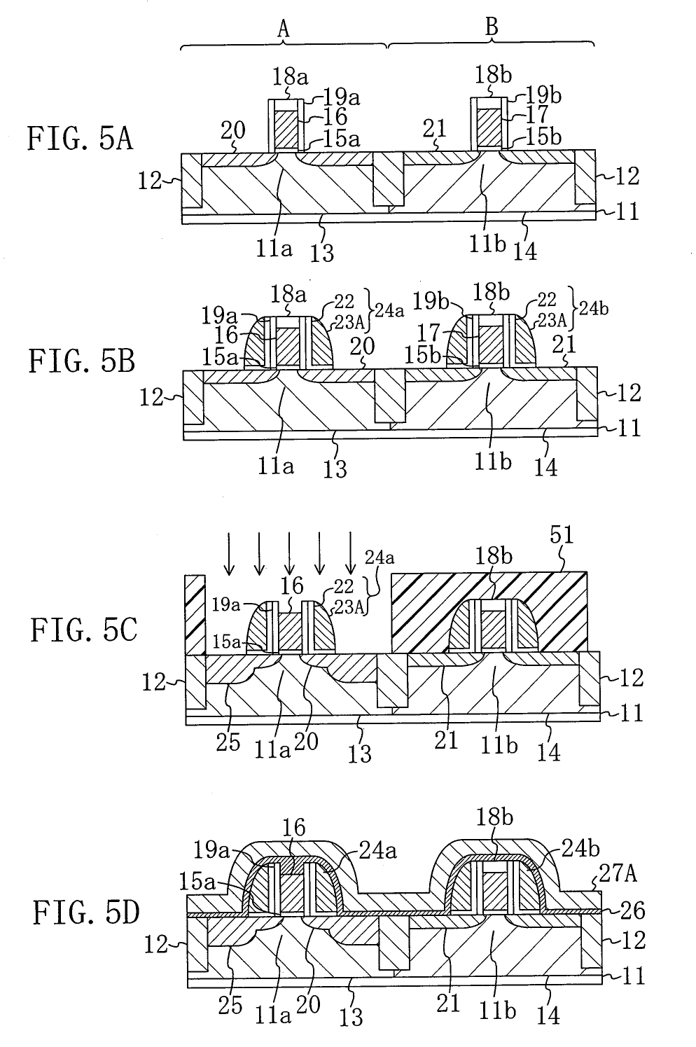

FIGS. 5A to 5D, 6A to 6D and 7A to 7C are cross-sectional views sequentially illustrating process steps of a fabrication method for a semiconductor device of Embodiment 2 of the present invention.

First, as shown in FIG. 5A, the principal surface of a semiconductor substrate 11 made of silicon (Si), which has (100) plane as its principal surface, is partitioned into an n-type transistor region A and a p-type transistor region B with an isolation region 12. An active region 11a is therefore formed as a portion of the semiconductor substrate 11 surrounded with the isolation region 12 in the n-type transistor region A, and an active region 11b is formed as a portion of the semiconductor substrate 11 surrounded with the isolation region 12 in the p-type transistor region B. A p-type well 13 is then formed in the n-type transistor region A of the semiconductor substrate 11, and an n-type well 14 is formed in the p-type transistor region A thereof. Thereafter, an n-type gate electrode 16 made of polysilicon is formed, by patterning using a hard mask 18a, on the active region 11a in the n-type transistor region A with a gate insulating film 15a interposed therebetween. Likewise, a p-type gate electrode 17 made of polysilicon is formed, by patterning using a hard mask 18b, on the active region 11b in the p-type transistor region B with a gate insulating film 15b interposed therebetween. As the hard masks 18a and 18b, a silicon oxide (SiO₂) film having a thickness of about 60 nm to 80 nm may be used. Sidewall films (sidewall spacers) 19a and 19b made of silicon oxide (SiO₂) are then formed on the side faces of the gate electrodes 16 and 17, respectively. Using the sidewall films 19a, the hard mask 18a and the n-type gate electrode 16 as a mask, an n-type impurity is implanted to form n-type extension regions 20 in the active region 11a in the n-type transistor region A. Likewise, using the sidewall films 19b, the hard mask 18b and the p-type gate electrode 17 as a mask, a p-type impurity is implanted to form p-type extension regions 21 in the active region 11b in the p-type transistor region B.

As shown in FIG. 5B, a multilayer film made of a silicon oxide film 22 and a silicon oxide nitride film 23A, for example, is deposited over the entire surface of the semiconductor substrate 11, and the deposited multilayer film is etched back, to form sidewalls 24a and 24b on the side faces of the n-type gate electrode 16 and the p-type gate electrode 17, respectively, with the sidewall films 19a and 19b interposed therebetween. Each of the sidewalls 24a and 24b is composed of an inner sidewall of the silicon oxide film 22 having an L-shaped cross section and an outer sidewall of the silicon oxide nitride film 23A formed on the inner sidewall. The sidewalls 24a and 24b are not necessarily made of a multilayer film.

As shown in FIG. 5C, a first resist pattern 51 having an opening corresponding to the n-type transistor region A is formed on the semiconductor substrate 11. The hard mask 18a on the n-type gate electrode 16 exposed in the opening of the first resist pattern 51 is then removed, and thereafter, arsenic (As) is implanted in the active region 11a using the first resist pattern 51, the n-type gate electrode 16, the sidewall films 19a and the sidewalls 24a as a mask, to form n-type source/drain regions 25 in portions of the upper part of the p-type well 13 located outside of the sidewalls 24a. During this implantation, arsenic is also implanted in the n-type gate electrode 16, and this makes the grain size of the polysilicon constituting the n-type gate electrode 16 larger than the grain size of the polysilicon constituting the p-type gate electrode 17. With this enlarging, tensile stress strain in the gate length direction occurs in the channel region of the active region 11a located under the n-type gate electrode 16.

As shown in FIG. 5D, the first resist pattern 51 is removed, and thereafter, an underlying film 26 made of silicon oxide and a stress strain producing film 27A made of silicon nitride are sequentially deposited on the entire surface of the semiconductor substrate 11 by CVD so as to cover the n-type gate electrode 16 together with the sidewall films 19a and the sidewalls 24a and also the hard mask 18b on the p-type gate electrode 17 together with the sidewall films 19b and the sidewalls 24b. In the illustrated example, the thickness of the underlying film 26 is about 5 nm to 15 nm, and the thickness of the stress strain producing film 27A is about 15 nm to 50 nm. The stress strain producing film 27A is formed under conditions with which tensile stress strain in the gate length direction will be produced in the channel region of the active region 11a under the n-type gate electrode 16. The underlying film 26 is not necessarily provided.

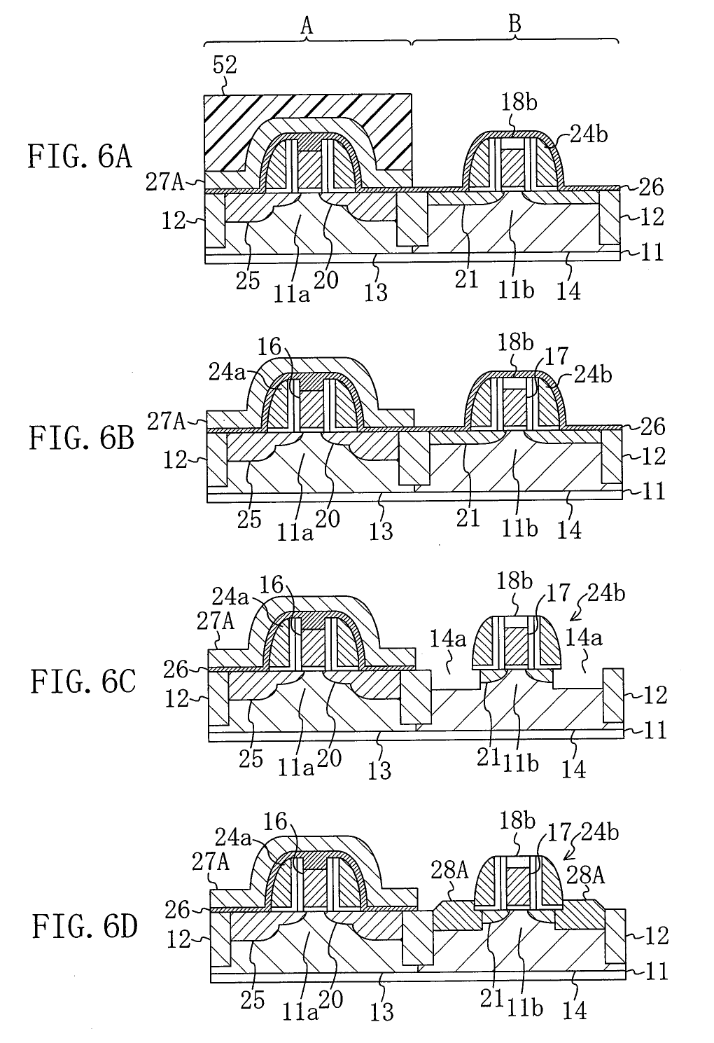

As shown in FIG. 6A, a second resist pattern 52 having an opening corresponding to the p-type transistor region B is formed on the semiconductor substrate 11. Using the second resist pattern 52 as a mask, the portion of the stress strain producing film 27A formed on the p-type transistor region B is removed with hot phosphoric acid and the like.

As shown in FIG. 6B, the second resist pattern 52 is removed, and thereafter, annealing is made for the resultant semiconductor substrate 11 at about 1050° C. for about 0 to 10 seconds, to produce tensile stress strain in the gate length direction in the channel region of the active region 11a under the n-type gate electrode 16.

As shown in FIG. 6C, the underlying film 26 formed on the p-type transistor region B is removed with buffered hydrogen fluoride (BHF) and the like using the stress strain producing film 27A on the n-type transistor region A as a mask. Subsequently, the portions of the active region 11b (semiconductor substrate 11) exposed in the p-type transistor region B are etched using the stress strain producing film 27 on the n-type transistor region A and the hard mask 18b, the sidewall films 19b and the sidewalls 24b on the p-type transistor region B as a mask. With this etching, recesses 14a are formed in portions of the upper part of the n-type well 14 in the active region 11b located outside of the sidewalls 24b. The depth of the recesses 14a is desirably about 40 nm to 60 nm when the height of the p-type gate electrode 17 is 100 nm.

As shown in FIG. 6D, while the active region 11a in the n-type transistor region A is kept covered with the stress strain producing film 27A and the underlying film 26, semiconductor layers 28A made of silicon germanium (SiGe) are epitaxially grown in the recesses 14a formed in the active regions 11b selectively. Having such semiconductor layers 28A made of mixed crystal including Ge larger in lattice constant than Si, compressive stress strain in the gate length direction occurs in the channel region of the active region 11b under the p-type gate electrode 17. The proportion of Ge in SiGe is desirably about 15% to 30%. The protrusion of the semiconductor layers 28A from the principal surface of the semiconductor substrate 11 is desirably about 20% to 30% of the height of the p-type gate electrode 17.

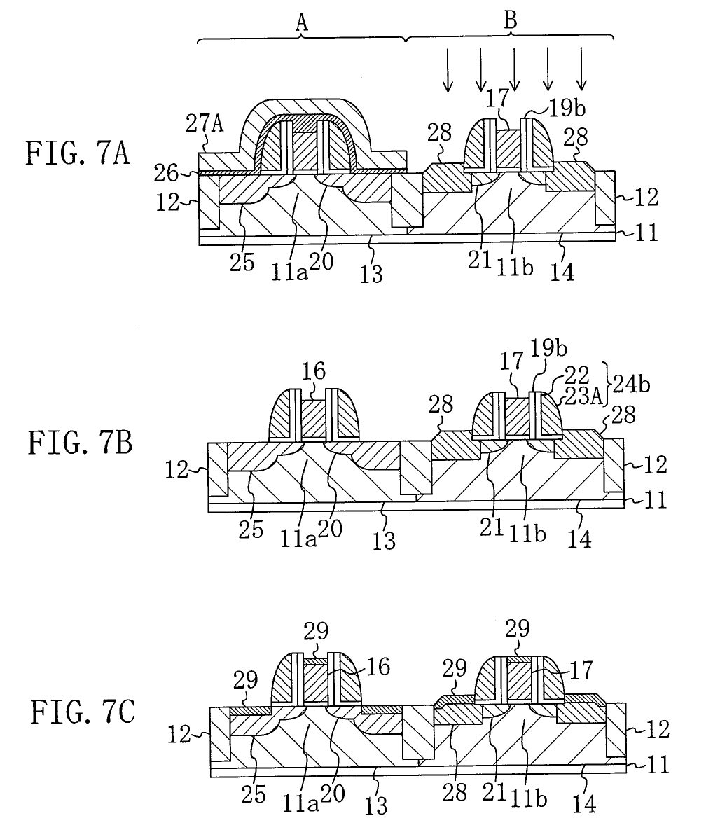

As shown in FIG. 7A, using the stress strain producing film 27A covering the n-type transistor region A of the semiconductor substrate 11 as a mask, the hard mask 18b on the p-type gate electrode 17 is removed. Subsequently, boron (B) is implanted in the active region 11b using the stress strain producing film 27A, the p-type gate electrode 17, the sidewall films 19b and the sidewalls 24b as a mask, to form p-type source/drain regions 28 in the active region 11b including the semiconductor layers 28A made of SiGe.

As shown in FIG. 7B, the stress strain producing film 27A and the underlying film 26 covering the n-type transistor region A of the semiconductor substrate 11 are removed by anisotropy etching such as dry etching with sulfur hexafluoride (SF₆) as a main ingredient. With this dry etching for removing the stress strain producing film 27A and the underlying film 26, the sidewalls 24b made of the silicon oxide film 22 and the silicon oxide nitride film 23A and the sidewall films 19b made of silicon oxide formed on the side faces of the p-type gate electrode 17 are also thinned. Therefore, the height and width of the sidewalls 24b become smaller than the height and width of the sidewalls 24a formed on the side faces of the n-type gate electrode 16.

As shown in FIG. 7C, a metal layer made of nickel (Ni), cobalt (Co), platinum (Pt) or the like is deposited on the resultant semiconductor substrate 11 by sputtering and the like, and the deposited metal layer is annealed, to form metal silicide layers 29 in the upper portions of the n-type source/drain regions 25, the n-type gate electrode 16, the p-type source/drain regions 28 (including the semiconductor layers 28A made of SiGe) and the p-type gate electrode 17.

By following the process described above, it is possible to implement a semiconductor device in which tensile stress strain in the gate length direction occurs in the channel region of the active region 11a in the n-type transistor region A while compressive stress strain in the gate length direction occurs in the channel region of the active region 11b in the p-type transistor region B.

Moreover, in Embodiment 2, the tress strain forming film 27A for producing tensile stress strain in the channel region of the active region 11a in the n-type transistor region A is used both as the etching mask for formation of the recesses 14a in the active region 11b in the p-type transistor region B shown in FIG. 6C and as the mask for implantation of boron in the active region 11b in the p-type transistor region B shown in FIG. 7A. This further simplifies the semiconductor device fabrication process.

In Embodiment 2, the stress strain producing film 27A was made to have a thickness of 15 nm to 50 nm to serve as the mask for the ion implantation in the p-type transistor region B. The stress strain producing film 27A can however be thinned as far as ions are not allowed to penetrate therethrough during the ion implantation, to thereby be adaptable to scaling-down involving reduction in the spacing between the n-type gate electrode 16 and the p-type gate electrode 17.

If it becomes necessary to thin the stress strain producing film 27A to a degree that ions may penetrate therethrough during the ion implantation for further scaling-down implementation, Embodiment 1 will be able to support such a case.

In Embodiment 1, the alteration thereto and Embodiment 2 described above, the p-type source/drain regions 28 were the same in size (junction depth) as the semiconductor layers 28A. Alternatively, the p-type source/drain regions 28 may be made smaller than the semiconductor layers 28A to exist only inside (in the upper portion) of the semiconductor layers 28A, or may be made larger than the semiconductor layers 28A to extend to the semiconductor substrate 11 (active region 11b).

Although polysilicon was used for the n-type gate electrode 16 and the p-type gate electrode 17, the material is not limited to polysilicon, but may be amorphous silicon, for example. Otherwise, metal gates may be adopted.

As described above, according to the present invention, a semiconductor device in which different types of stress are produced in elements different in conductivity type can be fabricated in a more simplified manner. Hence, the present invention is useful for a semiconductor device in which stress strain is imparted to the channel regions of MIS transistors, for example, and a fabrication method for the same.

What is claimed is:

1. A semiconductor device comprising:
a first MIS transistor formed on a first region of a first conductivity type in a semiconductor substrate; and
a second MIS transistor formed on a second region of a second conductivity type in the semiconductor substrate,
wherein the first MIS transistor has a first gate insulating film and a first gate electrode formed on the first region, first sidewalls formed on side faces of the first gate electrode, and first source/drain regions of the second conductivity type made of silicon formed in portions of the first region located outside of the first sidewalls,
the second MIS transistor has a second gate insulating film and a second gate electrode formed on the second region, second sidewalls formed on side faces of the second gate electrode, and second source/drain regions of the first conductivity type including silicon germanium formed in portions of the second region located outside of the second sidewalls, and
the second sidewalls are smaller in height than the first sidewalls.

2. The device of claim 1, wherein the second sidewalls are smaller in width than the first sidewalls.

3. The device of claim 1, further comprising:
recesses formed in portions of the second region located outside of the second sidewalls; and
semiconductor regions made of silicon germanium formed in the recesses in contact with the semiconductor substrate,
wherein the second source/drain regions are formed in the semiconductor regions.

4. The device of claim 3, wherein the proportion of germanium in the semiconductor regions is not less than 15% and not more than 30%.

5. The device of claim 3, wherein the top surfaces of the semiconductor regions protrude upward from the surface of a portion of the second region located under the second gate electrode.

6. The device of claim 1, wherein tensile stress strain occurs in the gate length direction in a channel region of the first region located under the first gate electrode, and
compressive stress strain occurs in the gate length direction in a channel region of the second region located under the second gate electrode.

7. The device of claim 1, wherein the main component of the first gate electrode and the second gate electrode is silicon, and
the grain size of silicon crystal in the first gate electrode is greater than the grain size of silicon crystal in the second gate electrode.

8. The device of claim 1, further comprising:
a first insulating film formed on the first region to cover the first sidewalls and the first gate electrode and also to produce tensile stress strain in the gate length direction; and
a second insulating film formed on the second region to cover the second sidewalls and the second gate electrode and also to produce compressive stress strain in the gate length direction

9. The device of claim 1, wherein metal silicide layers are formed in upper portions of the first source/drain regions, the first gate electrode, the second source/drain regions and the second gate electrode.

10. A fabrication method for a semiconductor device comprising the steps of:
(a) forming a first gate insulating film and a first gate electrode, in this order, on a first region of a first conductivity type in a semiconductor substrate, and forming a second gate insulating film and a second gate electrode, in this order, on a second region of a second conductivity type in the semiconductor substrate;
(b) forming first sidewalls and second sidewalls, both being insulative, on both side faces of the first gate electrode and the second gate electrode, respectively;
(c) forming a first insulating film on the first region to cover the first sidewalls and the first gate electrode and to impart stress strain to the first region;
(d) imparting stress strain to the first region by means of the first insulating film by heating the semiconductor substrate;
(e) after the step (d), forming recesses in the second region to be located outside of the second sidewalls by etching upper portions of the second region using the first insulating film on the first region and the second sidewalls on the second region as a mask; and
(f) forming semiconductor regions made of silicon germanium in the recesses in the second region.

11. The method of claim 10, wherein the step (a) comprises the step of forming a first hard mask on the first gate electrode and forming a second hard mask on the second gate electrode, and
in the step (e), recesses are formed by etching upper portions of the second region using the second hard mask and the second sidewalls as a mask.

12. The method of claim 11, further comprising, between the step (b) and the step (c), the step of:
(g) forming first source/drain regions of the second conductivity type by implanting an impurity of the second conductivity type in the first region selectively using the first gate electrode and the first sidewalls as a mask.

13. The method of claim 12, wherein the main component of the first gate electrode is silicon, and
in the step (g), the impurity of the second conductivity type is implanted after removal of the first hard mask, to allow the impurity of the second conductivity type to be implanted also in the first gate electrode.

14. The method of claim 10, further comprising, after the step (f), the step of:
(h) forming second source/drain regions of the first conductivity type in the semiconductor regions by implanting an impurity of the first conductivity type in the semiconductor regions in the second region selectively using the second gate electrode and the second sidewalls as a mask.

15. The method of claim 14, wherein in the step (h), the first region is covered with the first insulating film.

16. The method of claim 14, wherein in the step (h), the first region is covered with a mask pattern covering the first insulating film.

17. The method of claim 10, further comprising, after the step (f), the step of
(i) removing the first insulating film on the first region,
wherein in the step (i), the second sidewalls become smaller in height than the first sidewalls.

18. The method of claim 17, further comprising, after the step (i), the step of:
(j) removing the first sidewalls and the second sidewalls.

19. The method of claim 18, wherein in the step (b), each of the first sidewalls and the second sidewalls is formed of a plurality of insulating films different in composition, and
in the step (j), only the outer one of the plurality of insulating films constituting each of the first sidewalls and the second sidewalls is selectively removed.

20. The method of claim 10, the step (c) includes the step of forming a second insulating film different in composition from the first insulating film before the formation of the first insulating film.
